(19) United States
(12) Patent Application Publication
(10) Pub. No.: US 2022/0173088 A1
(43) Pub. Date: Jun. 2, 2022

(54) METHOD OF MANUFACTURING A DISPLAY MODULE AND FULL SCREEN IMAGE DISPLAY DEVICE INCLUDING A DISPLAY MODULE PREPARED IN ACCORDANCE WITH THE AFOREMENTIONED METHOD

(71) Applicant: ASTI GLOBAL INC., TAIWAN, Taichung City (TW)

(72) Inventors: Chien-Shou Liao, Taichung City (TW); Shao-Wei Huang, Taichung City (TW); Yu-Min Huang, Taichung City (TW)

(73) Assignee: ASTI GLOBAL INC., TAIWAN, Taichung City (TW)

(21) Appl. No.: 17/523,888

(22) Filed: Nov. 10, 2021

Related U.S. Application Data
(60) Provisional application No. 63/120,221, filed on Dec. 2, 2020.

(30) Foreign Application Priority Data
Oct. 26, 2021 (TW) 110139605

(51) Int. Cl. H01L 25/16; H01L 27/15

(52) U.S. Cl. CPC H01L 25/167; H01L 27/156

(57) ABSTRACT

A method of manufacturing a display module is provided and includes providing a substrate; disposing a plurality of light emitting components on the substrate in an array arrangement; and disposing at least one optical sensor on the substrate, wherein the at least one optical sensor is located between corresponding two of the plurality of light emitting components when the plurality of light emitting components and the at least one optical sensor are disposed on the substrate. Besides, a full screen image display device including a display module prepared in accordance with the aforementioned method is provided. The present invention can provide a full screen image without any notch.

### CROSS REFERENCE TO RELATED APPLICATIONS

This application claims the benefit of U.S. Provisional Application No. 63/120,221, filed on Dec. 2, 2020, and Taiwan Application No. 110139605, filed on Oct. 26, 2021, and the entire contents of which are hereby incorporated by reference.

### BACKGROUND OF THE INVENTION

### 1. Field of the Invention

The present invention relates to a method of manufacturing a display module and a full screen image display device including a display module prepared in accordance with the aforementioned method, and more specifically, to a method of manufacturing a display module for displaying an image without any notch, and a full screen image display device including a display module prepared in accordance with the aforementioned method.

### 2. Description of the Prior Art

A portable electronic device, such as a mobile phone or a tablet computer, usually includes a display module and an optical module. As for the conventional portable electronic device, the display module includes a first substrate and light emitting components disposed on the first substrate, and the optical module includes a second substrate and optical sensors disposed on the second substrate. The first substrate and the second substrate are disposed within different areas or different regions separately. In other words, the first substrate is disposed within an area or a region in which the second substrate is not disposed. When the display module emits light for displaying an image, the area or the region in which the second substrate of the optical module is disposed does not emit light therethrough, so that there is a black notch formed on the image, which negatively impacts on visual experience.

### SUMMARY OF THE INVENTION

Therefore, it is an objective of the present invention to provide a method of manufacturing a display module for displaying an image without any notch, and a full screen image display device including a display module prepared in accordance with the aforementioned method for solving the aforementioned problem.

In order to achieve the aforementioned objective, the present invention discloses a method of manufacturing a display module. The method includes providing a substrate; disposing a plurality of light emitting components on the substrate in an array arrangement; and disposing at least one optical sensor on the substrate, wherein the at least one optical sensor is located between corresponding two of the plurality of light emitting components when the plurality of light emitting components and the at least one optical sensor are disposed on the substrate.

According to an embodiment of the present invention, the substrate is a silicon substrate, and the method further includes disposing the at least one optical sensor on the silicon substrate by semiconductor fabrication process, and then disposing the plurality of the light emitting components on the silicon substrate by semiconductor fabrication process.

According to an embodiment of the present invention, the substrate is a silicon substrate, and the method further includes disposing the plurality of the light emitting components on the silicon substrate by semiconductor fabrication process, and then disposing the at least one optical sensor on the silicon substrate by semiconductor fabrication process.

According to an embodiment of the present invention, the substrate is a silicon substrate, and the method further includes disposing the at least one optical sensor on the silicon substrate by semiconductor fabrication process, and then disposing the plurality of the light emitting components on the silicon substrate by transfer process.

According to an embodiment of the present invention, the substrate is a silicon substrate, and the method further includes disposing the plurality of the light emitting components on the silicon substrate by semiconductor fabrication process, and then disposing the at least one optical sensor on the silicon substrate by transfer process.

According to an embodiment of the present invention, the substrate is a silicon substrate, and the method further includes disposing the plurality of the light emitting components on the silicon substrate by transfer process, and then disposing the at least one optical sensor on the silicon substrate by transfer process.

According to an embodiment of the present invention, the substrate is a silicon substrate, and the method further includes disposing the at least one optical sensor on the silicon substrate by transfer process, and then disposing the plurality of the light emitting components on the silicon substrate by transfer process.

According to an embodiment of the present invention, the substrate is a glass substrate, and the method further includes disposing the plurality of the light emitting components on the glass substrate by transfer process, and then disposing the at least one optical sensor on the glass substrate by transfer process.

According to an embodiment of the present invention, the substrate is a glass substrate, and the method further includes disposing the at least one optical sensor on the glass substrate by transfer process, and then disposing the plurality of the light emitting components on the glass substrate by transfer process.

In order to achieve the aforementioned objective, the present invention further discloses a full screen image display device including a display module prepared in accordance with a method, and the method includes providing a substrate; disposing a plurality of light emitting components on the substrate in an array arrangement; and disposing at least one optical sensor on the substrate, wherein the at least one optical sensor is located between corresponding two of the plurality of light emitting components when the plurality of light emitting components and the at least one optical sensor are disposed on the substrate.

According to an embodiment of the present invention, the substrate is a silicon substrate, and the method further includes disposing the at least one optical sensor on the silicon substrate by semiconductor fabrication process, and then disposing the plurality of the light emitting components on the silicon substrate by semiconductor fabrication process.

According to an embodiment of the present invention, the substrate is a silicon substrate, and the method further includes disposing the plurality of the light emitting components on the silicon substrate by semiconductor fabrication process, and then disposing the at least one optical sensor on the silicon substrate by semiconductor fabrication process.

According to an embodiment of the present invention, the substrate is a silicon substrate, and the method further includes disposing the at least one optical sensor on the silicon substrate by semiconductor fabrication process, and then disposing the plurality of the light emitting components on the silicon substrate by transfer process.

According to an embodiment of the present invention, the substrate is a silicon substrate, and the method further includes disposing the plurality of the light emitting components on the silicon substrate by semiconductor fabrication process, and then disposing the at least one optical sensor on the silicon substrate by transfer process.

According to an embodiment of the present invention, the substrate is a silicon substrate, and the method further includes disposing the plurality of the light emitting components on the silicon substrate by transfer process, and then disposing the at least one optical sensor on the silicon substrate by transfer process.

According to an embodiment of the present invention, the substrate is a silicon substrate, and the method further includes disposing the at least one optical sensor on the silicon substrate by transfer process, and then disposing the plurality of the light emitting components on the silicon substrate by transfer process.

According to an embodiment of the present invention, the substrate is a glass substrate, and the method further includes disposing the plurality of the light emitting components on the glass substrate by transfer process, and then disposing the at least one optical sensor on the glass substrate by transfer process.

According to an embodiment of the present invention, the substrate is a glass substrate, and the method further includes disposing the at least one optical sensor on the glass substrate by transfer process, and then disposing the plurality of the light emitting components on the glass substrate by transfer process.

In summary, in the present invention, since the light emitting components and the optical sensor are disposed on the same substrate, and when the light emitting components and the optical sensor are disposed on the substrate, the optical sensor is located between the two corresponding light emitting components. Therefore, when the light emitting components emit light for displaying an image, the image can be a full screen image without any notch. Therefore, the present invention can effectively solve the problem of negatively impacting on visual experience due to a black notch formed on the image.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a full screen image display device according to an embodiment of the present invention.

FIG. 2 is a partial enlarged diagram of a display module according to the embodiment of the present invention.

FIG. 3 is a partial sectional diagram of the display module according to the embodiment of the present invention.

FIG. 4 is a flow chart of a method of manufacturing the display module according to the embodiment of the present invention.

### DETAILED DESCRIPTION

In order to illustrate technical specifications and structural features as well as achieved purposes and effects of the present invention, relevant embodiments and figures are described as follows.

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “left”, “right”, “front”, “back”, etc., is used with reference to the orientation of the Figure(s) being described. The components of the present invention can be positioned in a number of different orientations. As such, the directional terminology is used for purposes of illustration and is in no way limiting. Accordingly, the drawings and descriptions will be regarded as illustrative in nature and not as restrictive.

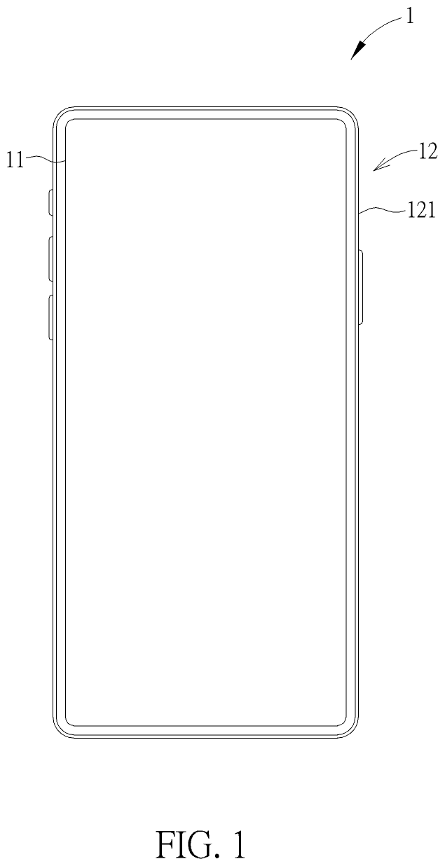

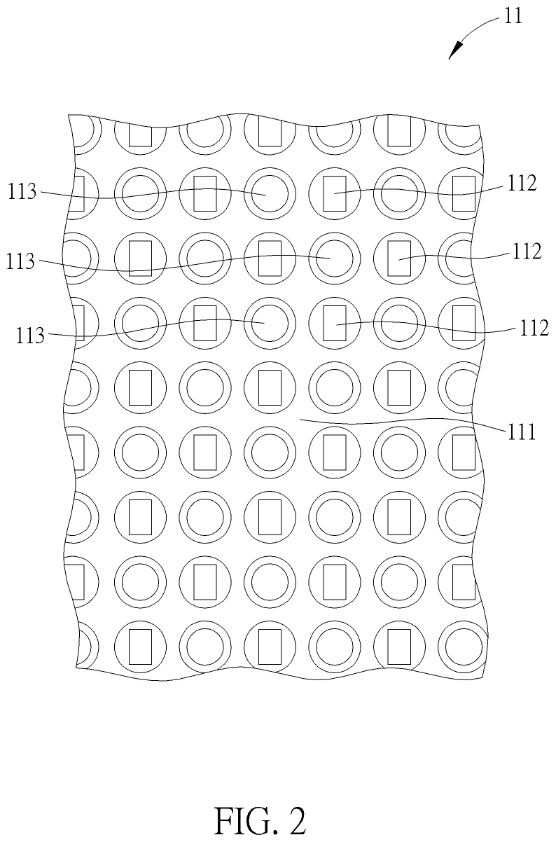

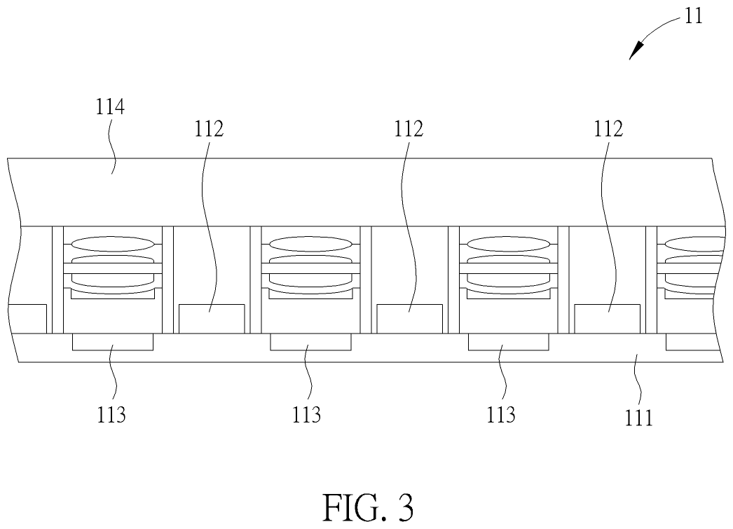

Please refer to FIG. 1 to FIG. 3. FIG. 1 is a schematic diagram of a full screen image display device 1 according to an embodiment of the present invention. FIG. 2 is a partial enlarged diagram of a display module 11 according to the embodiment of the present invention. FIG. 3 is a partial sectional diagram of the display module 11 according to the embodiment of the present invention. As shown in FIG. 1 to FIG. 3, the full screen image display device 1 can be a mobile phone. However, the present invention is not limited thereto. For example, in another embodiment, the full screen image display device can be a tablet computer, a laptop computer or a television. The full screen image display device 1 includes a display module 11 and a housing 12 for disposition of the display module 11. The housing 12 includes a bezel 121 and a rear cover, which is not shown in the figures. The display module 11 and the rear cover are installed on a front side and a rear side of the bezel 121, respectively. The display module 11 includes a substrate 111, a plurality of light emitting components 112, at least one optical sensor 113 and a window 114. In this embodiment, the display module 11 includes a plurality of optical sensors 113. However, the present invention is not limited to this embodiment. For example, in another embodiment, the display module can include only one optical sensor. Each of the light emitting components 112 and each of the optical sensors 113 are disposed on the substrate 111. The plurality of light emitting components 112 and the plurality of optical sensors 113 are disposed in a first array arrangement and a second array arrangement, respectively, and staggered with each other. When the plurality of light emitting components 112 and the plurality of optical sensors 113 are disposed on the substrate 111, each of the optical sensors 113 is located between the two corresponding light emitting components 112. Therefore, when the light emitting components 112 emit light for displaying an image, the image can be a full screen image without any notch. The window 114 is located above the substrate 111, the light emitting components 112 and the optical sensors 113. The window 114 can be made of transparent material, such as glass, so that light emitted from the light emitting components 112 is allowed to pass through the window 114 to an outside environment, and light from the outside environment is also allowed to pass through the window 114 to be captured by the optical sensors 113.

Specifically, the light emitting component 112 can be a micro light emitting diode (micro LED) or a mini light emitting diode (mini LED), and the optical sensor 113 can be a complementary metal-oxide-semiconductor (CMOS) image sensor. However, the present invention is not limited thereto. Preferably, the light emitting component 112 can be a micro LED or a mini LED capable of emitting red light, green light or blue light, and the optical sensor 113 can be a CMOS image sensor adapted for a front RGB camera, a front depth camera or a fingerprint sensor. However, the present invention is not limited thereto.

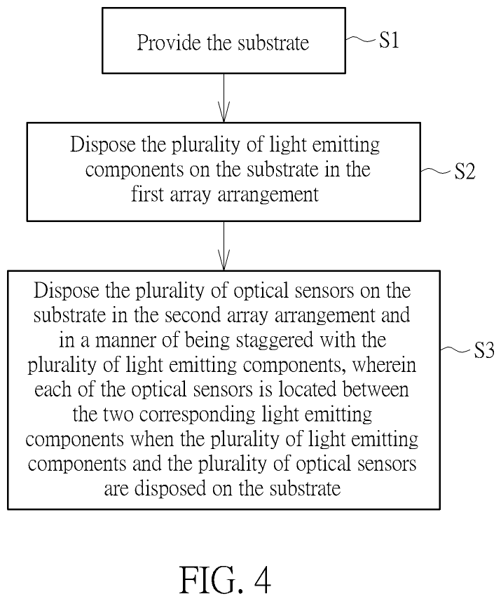

Please further refer to FIG. 4. FIG. 4 is a flow chart of a method of manufacturing the display module 11 according to the embodiment of the present invention. As shown in FIG. 4, the method includes the following steps:

Step S1: Provide the substrate 111.

Step S2: Dispose the plurality of light emitting components 112 on the substrate 111 in the first array arrangement.

Step S3: Dispose the plurality of optical sensors 113 on the substrate 111 in the second array arrangement and in a manner of being staggered with the plurality of light emitting components 112, wherein each of the optical sensors 113 is located between the two corresponding light emitting components 112 when the plurality of light emitting components 112 and the plurality of optical sensors 113 are disposed on the substrate 111.

It should be noticed that, in this embodiment, the substrate 111 can be a silicon substrate. Therefore, the plurality of optical sensors 113 can be disposed on the silicon substrate by semiconductor fabrication process firstly, and then the plurality of light emitting components 112 can be disposed on the silicon substrate by the same or different semiconductor fabrication process, wherein the semiconductor fabrication process can be, e.g., epitaxy, exposure, development, etching, physical vapor deposition (PVD) or chemical vapor deposition (CVD).

However, disposition order and method of the optical sensors and the light emitting components and material of the substrate are not limited to the aforementioned embodiment. In other words, ones of the light emitting components and the optical sensors can be disposed on the substrate firstly, and then the other ones of the light emitting components and the optical sensors can be disposed on the substrate. The optical sensors and/or the light emitting components also can be disposed on the substrate by the semiconductor fabrication process or by transfer process, wherein the transfer process can be, e.g., pick-and-place transfer, pin transfer, elastic impression transfer, laser-assisted transfer, ultrasonic-assisted transfer, Van der Waals force transfer, magnetic force transfer, electrostatic force transfer or any other mass transfer process. Furthermore, the substrate can be made of silicon or glass.

For example, in another embodiment, when the substrate is a silicon substrate, the light emitting components can be disposed on the silicon substrate by the semiconductor fabrication process firstly, and then the optical sensors can be disposed on the silicon substrate by the same or different semiconductor fabrication process. Alternatively, in another embodiment, when the substrate is a silicon substrate, the optical sensors can be disposed on the silicon substrate by the semiconductor fabrication process firstly, and then the light emitting components can be disposed on the silicon substrate by the transfer process. Alternatively, in another embodiment, when the substrate is a silicon substrate, the light emitting components can be disposed on the silicon substrate by the semiconductor fabrication process firstly, and then the optical sensors can be disposed on the silicon substrate by the transfer process. Alternatively, in another embodiment, when the substrate is a silicon substrate, the light emitting components can be disposed on the silicon substrate by the transfer process firstly, and then the optical sensors can be disposed on the silicon substrate by the transfer process. Alternatively, in another embodiment, when the substrate is a silicon substrate, the optical sensors can be disposed on the silicon substrate by the transfer process firstly, and then the light emitting components can be disposed on the silicon substrate by the transfer process. Alternatively, in another embodiment, when the substrate is a glass substrate, the light emitting components can be disposed on the glass substrate by the transfer process firstly, and then the optical sensors can be disposed on the glass substrate by the transfer process. Alternatively, in another embodiment, when the substrate is a glass substrate, the optical sensors can be disposed on the glass substrate by the transfer process firstly, and then the light emitting components can be disposed on the glass substrate by the transfer process.

Furthermore, the number of the optical sensor is not limited to the aforementioned embodiments. It depends on practical demands. For example, in another embodiment, the display module also can include only one optical sensor disposed between the two corresponding light emitting components by the semiconductor fabrication process or the transfer process, wherein the transfer process can be single die pick-and-place process or any other single die transfer process.

In contrast to the prior art, in the present invention, since the light emitting components and the optical sensor are disposed on the same substrate, and when the light emitting components and the optical sensor are disposed on the substrate, the optical sensor is located between the two corresponding light emitting components. Therefore, when the light emitting components emit light for displaying an image, the image can be a full screen image without any notch. Therefore, the present invention can effectively solve the problem of negatively impacting on visual experience due to a black notch formed on the image.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a display module, the method comprising:
providing a substrate;
disposing a plurality of light emitting components on the substrate in an array arrangement; and
disposing at least one optical sensor on the substrate, wherein the at least one optical sensor is located between corresponding two of the plurality of light emitting components when the plurality of light emitting components and the at least one optical sensor are disposed on the substrate.

2. The method of claim 1, wherein the substrate is a silicon substrate, and the method further comprises:
disposing the at least one optical sensor on the silicon substrate by semiconductor fabrication process, and then disposing the plurality of the light emitting components on the silicon substrate by semiconductor fabrication process.

3. The method of claim 1, wherein the substrate is a silicon substrate, and the method further comprises:
disposing the plurality of the light emitting components on the silicon substrate by semiconductor fabrication process, and then disposing the at least one optical sensor on the silicon substrate by semiconductor fabrication process.

4. The method of claim 1, wherein the substrate is a silicon substrate, and the method further comprises:
disposing the at least one optical sensor on the silicon substrate by semiconductor fabrication process, and then disposing the plurality of the light emitting components on the silicon substrate by transfer process.

5. The method of claim 1, wherein the substrate is a silicon substrate, and the method further comprises:
disposing the plurality of the light emitting components on the silicon substrate by semiconductor fabrication process, and then disposing the at least one optical sensor on the silicon substrate by transfer process.

6. The method of claim 1, wherein the substrate is a silicon substrate, and the method further comprises:
disposing the plurality of the light emitting components on the silicon substrate by transfer process, and then disposing the at least one optical sensor on the silicon substrate by transfer process.

7. The method of claim 1, wherein the substrate is a silicon substrate, and the method further comprises:
disposing the at least one optical sensor on the silicon substrate by transfer process, and then disposing the plurality of the light emitting components on the silicon substrate by transfer process.

8. The method of claim 1, wherein the substrate is a glass substrate, and the method further comprises:
disposing the plurality of the light emitting components on the glass substrate by transfer process, and then disposing the at least one optical sensor on the glass substrate by transfer process.

9. The method of claim 1, wherein the substrate is a glass substrate, and the method further comprises:
disposing the at least one optical sensor on the glass substrate by transfer process, and then disposing the plurality of the light emitting components on the glass substrate by transfer process.

10. A full screen image display device comprising a display module prepared in accordance with a method comprising:
providing a substrate;
disposing a plurality of light emitting components on the substrate in an array arrangement; and
disposing at least one optical sensor on the substrate, wherein the at least one optical sensor is located between corresponding two of the plurality of light emitting components when the plurality of light emitting components and the at least one optical sensor are disposed on the substrate.

11. The full screen image display device of claim 10, wherein the substrate is a silicon substrate, and the method further comprises:
disposing the at least one optical sensor on the silicon substrate by semiconductor fabrication process, and then disposing the plurality of the light emitting components on the silicon substrate by semiconductor fabrication process.

12. The full screen image display device of claim 10, wherein the substrate is a silicon substrate, and the method further comprises:
disposing the plurality of the light emitting components on the silicon substrate by semiconductor fabrication process, and then disposing the at least one optical sensor on the silicon substrate by semiconductor fabrication process.

13. The full screen image display device of claim 10, wherein the substrate is a silicon substrate, and the method further comprises:
disposing the at least one optical sensor on the silicon substrate by semiconductor fabrication process, and then disposing the plurality of the light emitting components on the silicon substrate by transfer process.

14. The full screen image display device of claim 10, wherein the substrate is a silicon substrate, and the method further comprises:
disposing the plurality of the light emitting components on the silicon substrate by semiconductor fabrication process, and then disposing the at least one optical sensor on the silicon substrate by transfer process.

15. The full screen image display device of claim 10, wherein the substrate is a silicon substrate, and the method further comprises:
disposing the plurality of the light emitting components on the silicon substrate by transfer process, and then disposing the at least one optical sensor on the silicon substrate by transfer process.

16. The full screen image display device of claim 10, wherein the substrate is a silicon substrate, and the method further comprises:
disposing the at least one optical sensor on the silicon substrate by transfer process, and then disposing the plurality of the light emitting components on the silicon substrate by transfer process.

17. The full screen image display device of claim 10, wherein the substrate is a glass substrate, and the method further comprises:
disposing the plurality of the light emitting components on the glass substrate by transfer process, and then disposing the at least one optical sensor on the glass substrate by transfer process.

18. The full screen image display device of claim 10, wherein the substrate is a glass substrate, and the method further comprises:
disposing the at least one optical sensor on the glass substrate by transfer process, and then disposing the plurality of the light emitting components on the glass substrate by transfer process.
